(19) United States
(12) Patent Application Publication
(10) Pub. No.: US 2009/0256217 A1
(43) Pub. Date: Oct. 15, 2009

(54) CARBON NANOTUBE MEMORY CELLS HAVING FLAT BOTTOM ELECTRODE CONTACT SURFACE

(75) Inventors: Hongquiang Lu, Fremont, CA (US); Peter A. Burke, Portland, OR (US); Wilbur Catabay, Saratoga, CA (US)

Correspondence Address: WILMERHALE/BOSTON, 60 STATE STREET, BOSTON, MA, 02109, US

(73) Assignee: LSI LOGIC CORPORATION, Milpitas, CA (US)

(21) Appl. No.: 12/102,700

(22) Filed: Apr. 14, 2008

(51) Int. Cl. H01L 27/00; H01L 21/02

(52) U.S. Cl. 257/415; 438/50

(57) ABSTRACT

The present invention is directed to structures and methods of fabricating nanotube electromechanical memory cells having a bottom electrode with a substantially planar contact surface. The bottom electrode is configured so that during the operation of the memory cell the nanotube crossbar of the cell can make contact with a substantially planar surface of the bottom electrode.

### CROSS REFERENCE TO RELATED APPLICATIONS

This application is a divisional of U.S. patent application Ser. No. 11/112,768, filed Apr. 21, 2005, entitled “CARBON NANOTUBE MEMORY CELLS HAVING FLAT BOTTOM ELECTRODE CONTACT SURFACE,” from which priority under 35 U.S.C. §120 is claimed. This application is incorporated herein by reference for all purposes.

### FIELD OF THE INVENTION

The invention described herein relates generally to memory devices that incorporate nanotube electromechanical elements in the individual memory cells. In particular, the present invention relates to methods, materials, and structures used to address the difficulties presented by the tungsten coring problem inherent in certain via fill methodologies especially where such problem is encountered in forming the lower electrode of a nanotube electromechanical memory cell.

### BACKGROUND OF THE INVENTION

Carbon nanotube technologies are beginning to make a significant impact on the electronic device industry. As is known to those having ordinary skill in the art, single-wall carbon nanotubes are quasi one-dimensional nano-scale wires. Such tubes can demonstrate metallic or semiconducting properties depending on their chirality and radius. One new area of implementation is that of non-volatile memory devices. One such application is described in U.S. Pat. No. 6,574,130 which is directed to hybrid circuits using nanotube electromechanical memory. This reference is hereby incorporated by reference for all purposes. Such nanotube electromechanical memory devices are also described in detail in WO 01/03208 which is incorporated by reference in its entirety. A fuller description of the operation of these devices can be obtained in these references.

These hybrid memory devices make use make use of nanotubes operating as mechanical switches that can be switched on and off by electrodes. The nanotubes operate by having an air gap above and below the nanotubes. The electrodes are selectively biased to bend the nanotubes to make electrical contact (or not) with various electrical contacts of a memory cell in order to set a memory state for the memory cell. Thus, good electrical contact between the nanotube and the electrode is desirable. Current fabrication methods and structures are less effective than desired at obtaining this desired electrical contact.

An example of a current method of constructing such a hybrid memory cell is described with respect to FIGS. 1(a) & 1(b). Referring to FIG. 1(a), a substrate 101 has a transistor formed thereon. As depicted the transistor has diffusion regions 101d and a gate electrode 101g. Over the transistor is formed an insulating layer 102 that typically includes electrical connections with the transistor and other circuit elements. One depicted connection is constructed using conductive via. This connection is typically referred to as a lower electrode 103 of a memory cell. Onto this substrate is formed a first support layer 111 (commonly formed using nitride materials) defining a lower air gap opening 112a that is filled with polysilicon sacrificial material. Over the sacrificial material is formed a nanotube electrical crossbar contact 113 that spans the lower air gap opening 112a. This nanotube crossbar 113 is typically formed of nanotubes or of nanotube “ribbons” etched or deposited to the desired size. As previously explained, methods of constructing such crossbars are well known in the art. One method is detailed in the 6,574,130 patent, which is incorporated above. The nanotube crossbar 113 is electrically connected with other circuit elements. Subsequently, a second support layer 114 is formed defining an upper opening 112b. Commonly, this second support layer 114 is formed of nitride or oxide materials. The upper opening is also filled with a sacrificial material (e.g., polysilicon). Thus, the upper sacrificial material is formed over the nanotube electrical crossbar 113. An electrode 115 is formed over the upper sacrificial material 112b and the sacrificial layers are removed to form the upper and lower airgaps. FIG. 1(b) is a depiction of FIG. 1(b) after a wet etch is used to remove the sacrificial layers 112a, 112b. Accordingly, the lower air gap 122a and an upper air gap 112b are formed above and below the nanotube crossbar 113. Finally, the substrate can be covered with a thick passivation layer 117 to complete the memory cell.

The salient problem addressed by this patent is the need for providing a good contact surface for the nanotube electrical crossbar 113 when it contacts the lower electrode 103. In particular, it is important that the lower electrode 103 have a substantially planar contact surface for contacting the nanotube electrical crossbar 113. In current processes, the lower electrode 103 is formed using a deposited tungsten plug to form the electrode. At the dimensions currently used for such electrodes (e.g., about 0.3 μm) tungsten deposition techniques are not entirely satisfactory. As is known to those having ordinary skill in the art, when the tungsten plugs are formed during via fill processes, the plugs tend to demonstrate a so-called “coring” phenomenon. This problem is schematically illustrated by FIGS. 1(c)-1(e). As the tungsten plug 103 is formed a core region of the plug remains empty forming a cavity 120. Due to the presence of the cavity, the top surface of the electrode is not substantially planar. In general, the cavity 120 is centralized about the center of the plug and surrounded by an outer region of tungsten material that is ground down in a CMP process (this CMP process can be responsible for the additional problem of dishing). The result of this problem is illustrated in the exaggerated cross-section view depicted by FIG. 1(e). The crossbar 113 when attracted by the lower electrode 103 makes uneven contact across the surface of the electrode 103. This leads to many different electrical sources of unreliability and unpredictability due to the variable nature of the electrical contact across the cavity 120. In general, the coring phenomenon results in poor and unpredictable electrical connection between the crossbar and the lower electrode. A nanotube electromechanical memory cell having no core cavity and a substantially planar electrical contact surface is can provide substantially enhance performance. Accordingly, there is a need for process methods and structures capable of reliable and repeatable fabrication of lower electrodes having substantially planar electrical contact surfaces without cavities.

### SUMMARY OF THE INVENTION

The embodiments of the present invention solve these and other problems. The principles of the present invention disclose methods of forming conductive plugs having substantially planar top surfaces and not having core cavities. In particular, the embodiments of the invention teach methods and structures useful in forming nanotube memory cells having lower electrodes with substantially planar top electrical contact surfaces for contacting the nanotube crossbars. As such, aspects of the present invention are directed to improved nanotube memory cells and methodologies for their construction.

In one embodiment, the invention describes a nanotube electromechanical memory cell formed on a substrate configured to include a transistor with a bottom electrode comprising a substantially planar contact surface enabling a nanotube crossbar of the memory cell to contact the substantially planar contact surface of the bottom electrode during operation of the memory cell.

In one implementation the invention describes a memory cell with a bottom electrode comprising a copper filled via having a substantially planar top contact surface.

In another embodiment the invention describes a bottom electrode comprising a via filled with a conductive material and a conducting top layer formed thereon such that the top layer comprises the substantially planar contact surface of the bottom electrode.

In another embodiment the invention describes a bottom electrode that includes a conductive pad having a substantially planar contact surface formed over a conductive via that is in electrical contact with an underlying transistor wherein the conductive pad comprises the substantially planar contact surface of the bottom electrode.

In another embodiment an electromechanical memory cell is described wherein the nanotube crossbar of the memory cell is offset relative to the core cavity of the bottom electrode so that in operation the a nanotube crossbar of the memory cell contacts the substantially planar contact surface of the outer region of the lower electrode.

Other embodiments of the invention disclose methods of forming the above-described embodiments. Additionally, embodiments of the invention concern the formation of via fill structures that do not have the core cavity.

These and other features and advantages of the present invention are described below with reference to the drawings.

### BRIEF DESCRIPTION OF THE DRAWINGS

The following detailed description will be more readily understood in conjunction with the accompanying drawings, in which:

FIGS. 1(a)-1(e) are simplified cross-section and plan views of various portions of a prior art nanotube electromechanical memory cell with particular attention directed to prior art lower electrodes.

FIG. 2 schematically illustrates simplified cross-section views of a semiconductor substrate including a generalized embodiment of a lower electrode employed in a nanotube electromechanical memory cell in accordance with the principles of the invention.

FIGS. 3(a)-3(e) schematically illustrate simplified cross-section views of a semiconductor substrate of an embodiment of a lower electrode or via plug employed in accordance with the principles of the invention.

FIGS. 4(a)-4(b) schematically illustrate simplified cross-section views of a semiconductor substrate of another embodiment of a lower electrode or via plug employed in accordance with the principles of the invention.

FIGS. 5(a)-5(c) schematically illustrate simplified cross-section views of a semiconductor substrate of yet anoth embodiment of a lower electrode or via plug employed in accordance with the principles of the invention.

FIGS. 6(a)-6(b) schematically illustrate simplified cross-section views of a semiconductor substrate of still another embodiment of a lower electrode or via plug employed in accordance with the principles of the invention.

FIGS. 7(a)-7(c) schematically depict simplified plan and cross-section views of yet another embodiment lower electrode employed in a nanotube electromechanical memory cell in accordance with the principles of the invention.

FIG. 8 is a simplified depiction of a semiconductor IC substrate having an array of memory cells schematically depicted thereon in accordance with the principles of the invention.

It is to be understood that, in the drawings, like reference numerals designate like structural elements. Also, it is understood that the depictions in the Figures are not necessarily to scale.

### DETAILED DESCRIPTION

The present invention has been particularly shown and described with respect to certain embodiments and specific features thereof. The embodiments set forth hereinbelow are to be taken as illustrative rather than limiting. It should be readily apparent to those of ordinary skill in the art that various changes and modifications in form and detail may be made without departing from the spirit and scope of the invention.

In the following detailed description, various materials and method embodiments for constructing substantially planar lower electrodes for nanotube electromechanical memory cells will be disclosed.

The disclosed embodiments include, among other things, a nanotube electromechanical memory cell having a substantially planar bottom electrode that facilitates enhances electrical performance at the interface between the crossbar and electrode. FIG. 2 is a schematic depiction of a nanotube electromechanical memory cell 200 having a substantially planar top surface 103T for the bottom electrode 103 in accordance with the principles of the invention. This is a step forward from the existing bottom electrodes which suffer from the coring problem. For the sake of completeness FIG. 2 depicts a portion a semiconductor wafer with a transistor formed thereon. The wafer can comprise any of a number of different semiconductor substrates (Si, GaAs, etc.). The depicted transistor includes a gate electrode 101g and, for example, one of the diffusion regions 101d. Typically, a CMOS type transistor is employed, but the inventors contemplate other transistor types. The transistor is typically covered with a dielectric layer and includes vias filled with conductive material 103 to electrically connect with the transistor. As indicated above, the conductive material 103 includes a substantially planar top surface 103. Moreover, the cell 200 includes a lower air gap below the nanotube crossbar element 113. Such crossbars can be a nanotube or a nanotube ribbon. An upper air gap is formed over the crossbar 113. The cell also includes an upper electrode 115. Commonly, the entire structure is treated with a passivation layer. Methods of forming such airgap chambers, nanotube crossbars, and upper electrodes are known. Examples of such methods are described in great detail in for example, U.S. Pat. No. 6,574,130, WO 01/03208, all of which are incorporated by reference in their entirety

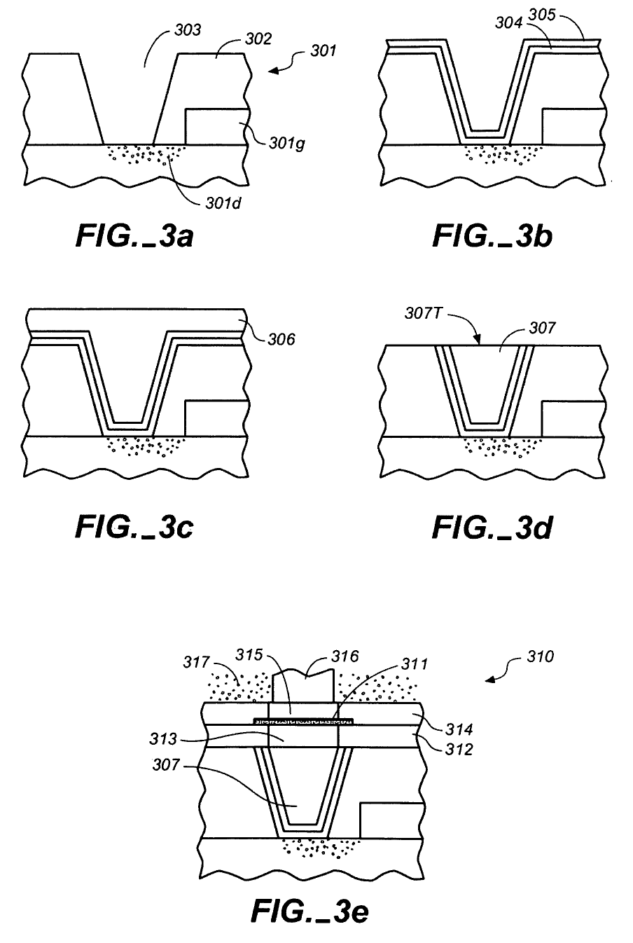

Of particular importance in this patent is the lower electrode and methods of its construction. For example, FIGS. 3(a)-3(e) pictographically illustrate one embodiment of such a lower electrode and a method of forming the lower electrode as part of a nanotube electromechanical memory cell. The lower electrode features a substantially planar top contact surface.

FIG. 3(a) schematically depicts a section view of a substrate 301 in readiness for further processing to form, for example, a lower electrode that can be employed in a nanotube electromechanical memory cell. The substrate includes a semiconductor surface (typically, silicon or gallium arsenide (GaAs) material) having a transistor formed thereon. The depicted transistor shows one of the diffusion regions 301d and the gate electrode 301g. An electrically insulating layer 302 is formed of the transistor and typically includes electrical connections with the transistor and other circuit elements. In some embodiments, the insulating layer 302 is a silicon dioxide layer or a thin nitride layer covered with a silicon dioxide layer. Of course, as is known to those having ordinary skill in the art, other electrically insulating materials can be employed. The insulating layer 302 also includes a via configured to access the diffusion regions 301d of the transistor. Typically, such vias are in the range of about 0.2-0.4 μm wide. In some embodiments, the walls of the vias are angled to allow easier filling of the via. Such wall angles are in the range of about 80-90° with one satisfactory embodiment having a wall angle of about 85°. By filling this via 303 with appropriate conductive material a lower electrode 103 of a memory cell can be formed. The depicted substrate 301 is in readiness for further processing to have a lower electrode formed.

In the depicted embodiment, a copper plug is to be used to fill the via instead of the standard tungsten. This will remedy the coring problem for the bottom electrode. As is known to those having ordinary skill in the art copper is capable of “poisoning” many different layers of a CMOS substrate if not properly encased. To that end, copper barrier layer(s) are then formed on the surface to encapsulate the copper. Referring to FIG. 3(b), an example of a barrier layer 304 is depicted. Any known copper barrier layer can be used. Example barrier layers are thin on the order of about 100 Å-1500 Å and sometimes thicker. Typical barriers can include bilayer materials and alloys. Examples of suitable materials include, but are not limited to: tantalum (Ta), titanium (Ta), TiN (titanium nitride), TaN (tantalum nitride) and especially bilayers like Ti/TiN or Ta/TaN. Also usable are TiSiN (titanium silicon nitride), WN (tungsten nitride) and other barrier materials known to those having ordinary skill in the art.

With continued reference to FIG. 3(b) a copper seed layer 305 is then formed on the barrier layer 304. This copper seed layer 305 can be formed by a number of processes known to those having ordinary skill in the art. In one example process, physical vapor deposition (PVD) can be used to form a thin seed layer 305 of copper. Such a seed layer 305 can be formed to a number of thicknesses, generally in the range of about 100 Å to about 2500 Å. In one embodiment, a layer 305 is formed to about 300-500 Å thick.

Referring now to FIG. 3(c), once the seed layer is formed a bulk copper layer 306 can be formed. Typically, this bulk copper layer 306 is formed using a plating technique. Electrochemical plating (ECP) is preferred. However, other embodiments can make use of electroless plating. The plating is continued until the via is filled. Due to the nature of the plating process no core cavity is formed in the electrode.

Then, as depicted in FIG. 3(d), the surface can be planarized. Typically, CMP techniques are used to remove the excess copper and barrier layers to form a lower electrode 307 having a substantially planar top contact surface 307T. Further processing is used to form a nanotube electromechanical memory cell 310. As depicted in FIG. 3(e) the nanotube electromechanical memory cell 310 includes a lower electrode 307 with a substantially planar top surface and no core cavity. The cell 310 includes a nanotube crossbar 311 positioned over the lower electrode 307 configured such that it spans an opening (defining a lower air gap) 312 in a lower support layer 313. Additionally, an upper support layer 314 is formed having an opening (defining a upper air gap) 315 that permits upward movement toward an upper electrode 316 that is formed above the crossbar 311. Typically, the cell is passivated with a dielectric material 317. Many such cells can be formed, for example, on a semiconductor substrate to produce a memory array.

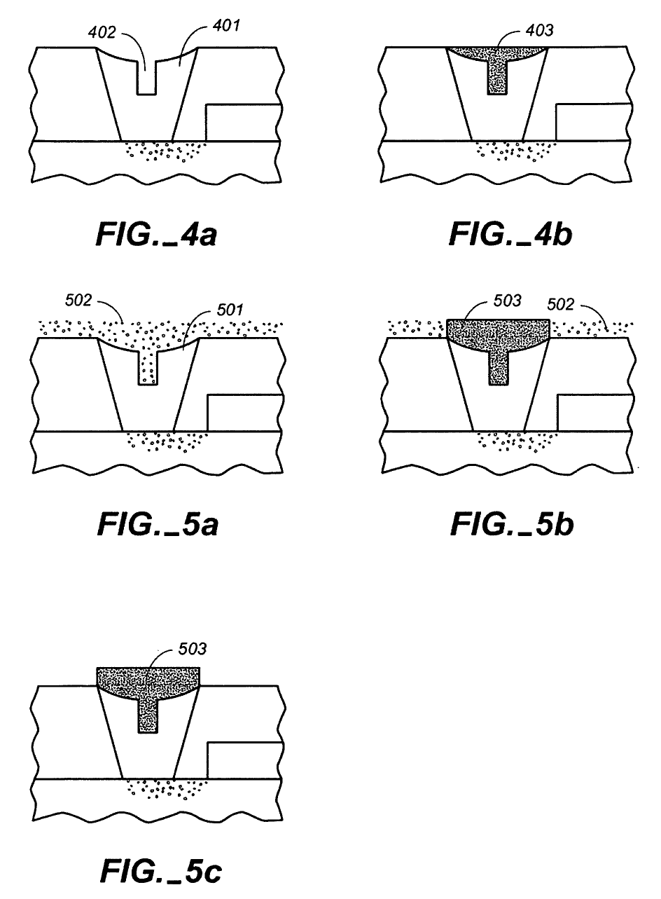

FIGS. 4(a) and 4(b) schematically depict yet another approach to forming a substrate having a lower electrode with a substantially planar top contact surface. In this embodiment, a substrate in readiness for forming a lower electrode is provided. One example of such a substrate is depicted in FIG. 3(a). Onto this substrate 301 is deposited a layer of tungsten. Typically, this layer of tungsten is deposited using chemical vapor deposition (CVD) process. Such CVD techniques include, but are not limited to, Atmospheric Pressure CVD (APCVD), Low Pressure CVD (LPCVD) and Plasma Enhanced CVD (PECVD), Metal-Organic CVD (MOCVD) and others. Additionally, this tungsten layer typically includes a cavity in the resulting plug. The tungsten layer is then planarized to remove the excess tungsten. Typically, CMP processes are used to planarize the surface. The surface of one such plug 401 after CMP is schematically depicted in FIG. 4(a). Frequently, such CMP processes result in a top surface that includes dishing. A process that could correct such dishing would be desirable. Additionally, as explained above, a cavity 402 is formed in the core region of the plug 401.

As shown in FIG. 4(b), a conductive material 403 is then plated onto the substrate to cover the plug 401 and to fill the cavity 402. One particularly suitable plating material 403 is cobalt tungsten phosphide (CoWP). Typically, a CoWP layer is plated on using, for example, electroless plating. Thus, the conductive material 403 is plated onto the plug 401. In the depicted embodiment, a conductive layer 403 comprising CoWP is plated onto the plug 401. Due to the nature of plating processes the cavity 401 and the dishing portions of the plug 401 become filled with the conducting material 403. Even more helpful is the selective nature of the plating process which plates onto only the exposed conductive plugs 401. Accordingly, no follow-up CMP process is required to remove the excess conductive material 403. This also means no further dishing is encountered if the CMP stem is dispensed with. Typically, the conductive material need be plated only to a depth of about 100-200 Å thick. Additionally, the inventors note that other platable conductive materials can also be used. Examples include, but are not limited to, gold, platinum, palladium, nickel, silver, tin, or aluminum as well as other suitable materials. Further processing can be used to form a nanotube electromechanical memory cell such as described for example with respect to FIG. 3(e).

FIGS. 5(a)-5(c) schematically depict yet another approach to forming a substrate having a lower electrode with a substantially planar top contact surface. In this embodiment, as with the previous embodiment, the provided substrate is in readiness for forming a lower electrode. Again, as before, FIG. 3(a) depicts a suitable substrate. Onto this substrate 301 is deposited a layer of tungsten. Again, this layer of tungsten can be deposited using chemical vapor deposition (CVD) process. Such CVD techniques include, but are not limited to, Atmospheric Pressure CVD (APCVD), Low Pressure CVD (LPCVD) and Plasma Enhanced CVD (PECVD), Metal-Organic CVD (MOCVD) and others. Also, as explained earlier the tungsten layer includes a cavity and is subject to planarization to remove the excess tungsten. The resulting plug 501 is schematically depicted in FIG. 5(a). Again, the cavity and dishing are shown. Subsequently, a silicon layer is deposited onto of the substrate surface to for a polysilicon layer 502. CVD type techniques being generally preferred but the invention is not limited to such. The polysilicon layer 502 covers the plug 501 and fills the cavity. The polysilicon layer 502 is typically deposited, for example, to a depth of about 100-200 Å thick.

Referring to FIG. 5(b), the substrate is then heated to a silicide forming temperature to react the silicon with the tungsten to form tungsten silicide a sufficiently conductive material. The reaction is selective forming a silicide layer 502 only in the regions proximate to the tungsten material. Thus, the silicide layer 503 is selectively formed on top of the plug (and in the cavity) forming a contiguous conductive surface over the face of the plug. Commonly, such a process can be achieved using an annealing furnace. For example, a rapid thermal annealing (RTA) process can proceed at any temperature hot enough to cause the silicide forming reaction but not so hot as to damage the rest of the structures on the substrate. For example, the substrate can be annealed at temperatures in the range of about 500° C. to about 800° C. for about 30 seconds to about 2 minutes. In one example implementation a two minute anneal at 800° C. can be employed. As is known to those having ordinary skill in the art other suitable process parameters can be employed. After annealing, the excess unreacted silicon 502 is removed. For example, a wet etch using TMAH (tetra methyl ammonium hydroxide) could be used. Additionally, a XeF₂ etch process can be used. In general, most other commonly used silicon etch techniques that have good etch selectivity with respect to silicon dioxide could be employed to remove the excess silicon 502. Typically, the silicide layer 503 comprises a substantially planar to surface without further processing. However, if the user desires further CMP processing can be conducted. Further processing can be used to form a nanotube electromechanical memory cell such as described for example with respect to FIG. 3(e).

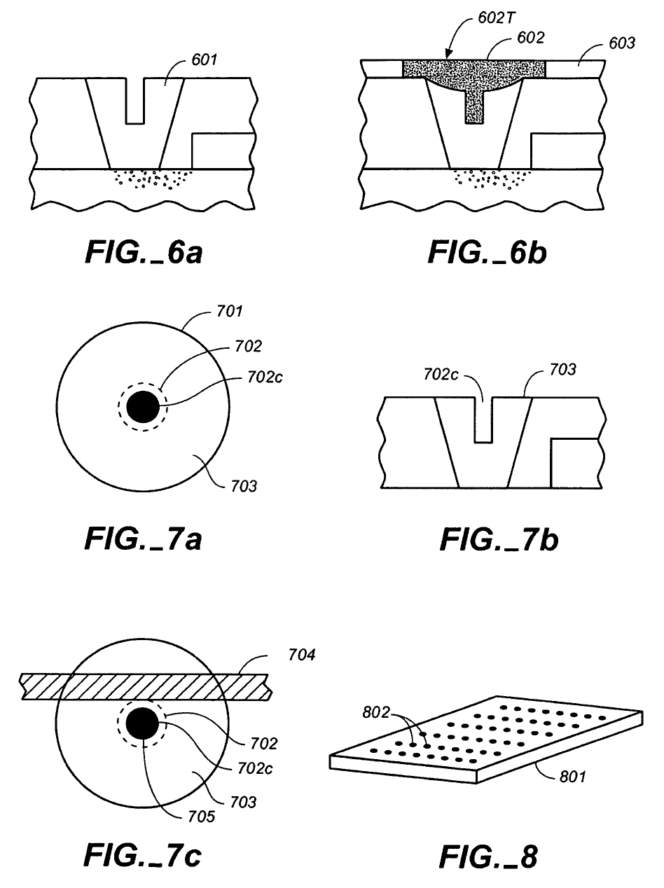

FIGS. 6(a) & 6(b) schematically depict yet another approach to forming a substrate having a lower electrode with a substantially planar top contact surface. In this embodiment, as with the previous embodiment, the provided substrate is in readiness for forming a lower electrode. Again, as before, a substrate such as depicted in FIG. 3(a) can be employed. Onto this substrate is deposited a layer of tungsten resulting in a structure as depicted in FIG. 4(a). Again, this layer of tungsten can be deposited using CVD or related process. This, as explained earlier results in a tungsten layer having a cavity and that is subject to planarization dishing. The resulting plug 601 is schematically depicted in FIG. 6(a).

The depicted embodiment utilizes a conductive pad 602 on formed on the plug 601 to form the substantially planar contact surface 602T of the bottom electrode. There are a number of embodiments for forming such conductive pads 602. In a first embodiment a supplemental layer 603 is formed such that a pattern of openings is formed therein. Commonly, the supplemental layer is formed of an electrically insulating material. One example of a suitable insulating material is silicon dioxide or other materials like low-K dielectrics and so on. The openings in the supplemental layer can be formed, for example, by selective deposition or pattern etching. In general, the openings are larger than the via diameter. The supplemental layer 603 is typically formed in the range of about 500-3000 Å thick. In one embodiment a layer of about 1000-1200 Å thick is used. Subsequently, a planarizable conducting material layer is formed on the substrate. One example of such a suitable material is tungsten. Aluminum, copper, silver, and other conductive materials can be used as well. Due to the shallow depth of these openings (e.g., commonly about 1000 Å) and the relatively wide opening, the coring problem does not occur in this layer. After this layer is formed the surface is then planarized to remove the excess conducting material layer to form a conductive pad 602 and also to provide a substantially planar top surface 602T for the resulting conductive pad 602. Such pads provide excellent electrical contact with the plug 601 and with the subsequently formed nanotube crossbar which can be formed by the further processing used to form a nanotube electromechanical memory cell such (See, for example, the discussion concerning FIG. 3(e)).

In another related approach, a layer of conductive material is deposited down on the substrate and then selectively etched. For example, the etching leaves the conductive material in place as the conductive pads 602. The conducting layer commonly, being formed in the range of about 500-3000 Å thick. In one embodiment a layer of about 1000-1200 Å thick is used. A suitable material for such a process is for example, the well understood aluminum material. Once the etched pattern is completed, a supplemental layer is formed over the conductive material. For example, as above, an electrically insulating material is deposited over the surface to form the supplemental layer. For example, silicon dioxide or other dielectric materials could be used. A CMP process is then used to remove the excess dielectric material layer to form an supplemental layer 603 and planarize the top surface of the conductive pad 602 to provide a substantially planar top surface 602T for the resulting conductive pad 602. The inventors further contemplate that numerous materials can be employed to form the substantially planar conductive pads 602. A few examples include but are not limited to copper, gold, nickel, palladium, platinum, silver, tin, aluminum, and alloys thereof.

FIGS. 7(a)-7(c) schematically depict yet another approach to forming a substrate having a lower electrode with a substantially planar top contact surface. In this embodiment, the nanotube crossbar is formed such that it overlies the substantially planar surface of a lower electrode and does not overlie the core cavity region of the lower electrode. Accordingly, when the crossbar contacts the underlying lower electrode it contacts a substantially flat surface thereby avoiding the difficulties inherent in the prior art. This concept is illustrated in conjunction with the following description of FIGS. 7(a)-7(c). FIG. 7(a) is a top down view of the top surface of a bottom electrode 701. A core void region 702 includes a cavity 702c commonly near the center of the via in which the electrode is formed. As described previously, such electrodes are commonly in the range of 0.2-0.4 μm in diameter. However, the scope of the invention is intended to apply to even smaller electrodes. Around the core void region 702 is an outer region 703 that is substantially planar in nature. FIG. 7(b) provides a cross section view of the same electrode to move clearly identify the cavity 702c and the substantially planar outer region 703.

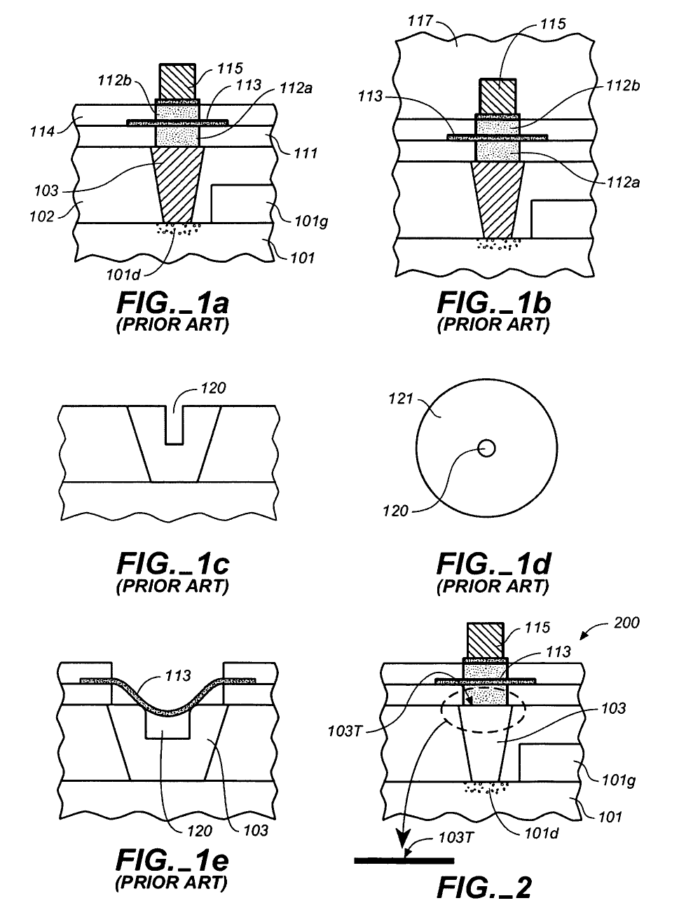

As is known to those having ordinary skill in the art, the nanotube crossbars of the prior art are generally centered on the middle of the electrode leading to the problem of the crossbar contacting the void in the middle of the electrode. FIG. 1(e) and the discussions pertaining thereto have previously described this problem. Commonly, nanotube structures are very thin. For example, a typical nanotube ribbon is on the order of about 30 Å wide. Thus, if the ribbin is offset some amount from the middle of the electrode, when it is activated in the operation of the memory cell it will not contact the cavity. Accordingly, it will contact the substantially planar portion of the electrode to make good electrical contact with the crossbar. Reference to FIG. 7(c) illustrates this point. The nanotube crossbar ribbon 704 is offset from the center 705 (and the cavity 702c) of the electrode 701 a distance sufficient so that when the electrode 701 is activated to attract the crossbar 702c that the crossbar contacts the substantially planar outer region 703 of the electrode and not the cavity 702c.

Commonly such structures as described herein are implemented in the electromechanical memory cells of an integrated circuit that typically includes a plurality of electromechanical memory cells. These electromechanical memory cells 802 are schematically depicted in FIG. 8 which depicts a IC chip 801 having an array of electromechanical memory cells 802 formed thereon.

Additionally, the inventors would like to point out that although described in the context of electromechanical memory cells the present embodiments also apply to via plug structures in general. The inventors point out that the coring problem occurs in all tungsten via structures. As yet it has not presented a significant hindrance to the operation of state of the art via structures. However, as via diameters continue to shrink with each passing generation of semiconductor development, the current density in the via plugs continues to rise. At some point in the near future the presence of these plug core cavities is going to present a serious obstacle to current flow in semiconductor devices. A plug formed without the cavity due to coring problems presents a serious advantage. Several of the previously disclosed embodiments depict via structures and illustrate methods of construction. Accordingly, the principles of the invention in general provide solutions to the via coring problems as well as electrode fabrication problems. Consequently, this disclosure provides solutions to these and other problems.

The present invention has been particularly shown and described with respect to certain embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Further, reference in the claims to an element in the singular is not intended to mean “one and only one” unless explicitly stated, but rather, “one or more”.

1. A nanotube electromechanical memory apparatus comprising:
a semiconductor substrate having a nanotube electromechanical memory cell formed thereon, the memory cell including a transistor with a bottom electrode comprising a substantially planar contact surface enabling a nanotube crossbar of the memory cell to contact the substantially planar contact surface of the bottom electrode during operation of the memory cells,
wherein the bottom electrode comprises a copper filled via enabling electrical contact with the transistor and having a substantially planar top surface comprising the substantially planar contact surface of the bottom electrode.

2. The apparatus of claim 1 comprising a copper barrier layer between the copper filled via and the bottom electrode.

3. The apparatus of claim 2, wherein the barrier layer is about 100 angstroms to about 1500 angstroms thick.

4. The apparatus of claim 2, wherein the barrier layer is selected from the group consisting of tantalum, titanium, titanium nitride, tantalum nitride, titanium silicon nitride, and tungsten nitride.

5. The apparatus of claim 2, wherein the barrier layer comprises a bilayer. 6. The apparatus 5, wherein the bilayer comprises at least one or Ti/TiN or Ti/TaN.

7. The apparatus of claim 2 comprising a copper seed layer between the barrier layer and the copper filled via.

8. The apparatus of claim 7, wherein the copper seed layer is between about 100 angstroms and about 2500 angstroms thick.

9. A method of a forming a bottom electrode contact surface in a nanotube electromechanical memory cell, the method comprising:
providing a semiconductor substrate having an opening formed therein, the opening configured to enable electrical contact with an underlying transistor of an electromechanical memory cell; and
forming a bottom electrode that extends into the opening enabling electrical connection with the transistor such that the bottom electrode has a substantially planar top contact surface enabling a nanotube crossbar of the memory cell to contact the top contact surface of the bottom electrode during operation of the memory cell,
wherein forming the bottom electrode comprises:
filling the opening with copper; and
planarizing the surface to form a substantially planar top contact surface.

10. The method of forming a bottom electrode contact surface in a nanotube electromechanical memory cell as in claim 9, wherein filling the opening with copper comprises:
forming a barrier layer on the substrate;
forming a conductive seed layer on the barrier;
plating the seed layer with copper to form a bulk copper that fills the opening; and
wherein planarizing the surface comprises chemical mechanical polishing of the surface to planarize the bulk copper layer in the opening to form a conductive via having a substantially planarized top surface enabling the nanotube crossbar of the memory cell to contact the substantially planarized top surface of the bottom electrode during operation of the memory cell.

11. The method of claim 10, wherein forming a conductive seed layer comprises physical vapor deposition.

12. The method of claim 10, wherein plating the seed layer with copper comprises electrochemical plating.

13. The method of claim 10, wherein the barrier layer is about 100 angstroms to about 1500 angstroms thick.

14. The method of claim 10, wherein the barrier layer is selected from the group consisting of tantalum, titanium, titanium nitride, tantalum nitride, titanium silicon nitride, and tungsten nitride.

15. The method of claim 10, wherein the barrier layer comprises a bilayer.

16. The method 10, wherein the bilaver comprises at least one or Ti/TiN or Ti/TaN.

17. The method of claim 10, wherein the copper seed layer is between about 100 angstroms and about 2500 angstroms thick.

18-21. (canceled)
